(19) United States
(12) Patent Application Publication
(10) Pub. No.: US 2026/0276739 A1
(43) Pub. Date: Sep. 17, 2026

(54) SYSTEMS AND METHODS FOR DETECTING A PRESENCE OF A FLOATING NEUTRAL CONDITION

(71) Applicant: Haier US Appliance Solutions, Inc., Wilmington, DE (US)

(72) Inventors: Stephan Roessler, Louisville, KY (US); Steven Keith Root, Buckner, KY (US)

(21) Appl. No.: 19/080,445

(22) Filed: Mar. 14, 2025

(51) Int. Cl. G01R 31/54; H02H 7/20

(52) U.S. Cl. CPC G01R 31/54; H02H 7/20

(57) ABSTRACT

Systems and methods for detecting the presence of a floating neutral condition are disclosed. The system includes a control circuit communicatively connected to a plurality of appliances. The control circuit is configured to instruct each appliance of the plurality of appliances to: record a first set of voltage data corresponding to at least one terminal of the electrical circuit; apply a load on the electrical circuit; record a second set of voltage data corresponding to the at least one terminal after the load is applied; and transmit the first and second sets of voltage data to the control circuit. The control circuit is further configured to: analyze the first and second sets of voltage data to detect a presence of a floating neutral condition; and instruct at least one appliance of the plurality of appliances to execute one or more operations based on the presence of the floating neutral condition.

### FIELD

The present disclosure relates generally to systems and methods for detecting the presence of a floating neutral condition.

### BACKGROUND

Floating neutral conditions have long caused damage to appliances and other electrical systems. Floating neutral conditions occur when the neutral wire in an electrical circuit is disconnected, loose, or improperly connected. When the neutral is floating, it creates an unstable return path for the current. During floating neutral conditions appliances that rely on consistent and balanced return paths for safe operation may experience voltage fluctuations or irregularities. When the floating neutral condition is present, it can lead to malfunctions or erratic operation of appliances connected to the electrical circuit. Previous attempts to identify floating neutral conditions have produced inaccurate and inconsistent results. These attempts have often identified the floating neutral condition once the damage has already been done to the appliances.

Accordingly, improved systems and methods for detecting a floating neutral condition are desired in the art. In particular, systems and methods for detecting floating neutral conditions that automatically identify the condition and take proactive corrective actions would be advantageous.

### BRIEF DESCRIPTION

Aspects and advantages of the invention in accordance with the present disclosure will be set forth in part in the following description, or may be obvious from the description, or may be learned through practice of the technology.

In accordance with one embodiment, a system for detecting the presence of a floating neutral condition is provided. The system includes a control circuit communicatively connected to a plurality of appliances, wherein each of the plurality of appliances are electrically connected to corresponding terminals of an electrical circuit. The control circuit is configured to instruct each of the plurality of appliances to: record a first set of voltage data corresponding to at least one terminal of the electrical circuit; apply a load on the electrical circuit; record a second set of voltage data corresponding to the at least one terminal after the load is applied; and transmit the first set of voltage data and the second set of voltage data to a control circuit. The control circuit is further configured to: analyze the first set of voltage data and the second set of voltage data to detect a presence of a floating neutral condition; and instruct at least one appliance of the plurality of appliances to execute one or more operations based on the presence of the floating neutral condition.

In accordance with another embodiment, a method for detecting the presence of a floating neutral condition is provided. The method includes instructing, using a control circuit, one or more appliances to: record a first set of voltage data corresponding to at least one terminal of an electrical circuit, wherein the one or more appliances are electrically connected to corresponding terminals of the electrical circuit; apply a load on the electrical circuit; record a second set of voltage data corresponding to the at least one terminal after the load is applied; and transmit the first set of voltage data and the second set of voltage data to the control circuit. The method includes analyzing, using the control circuit, the first set of voltage data and the second set of voltage data to detect a presence of a floating neutral condition. The method further includes instructing, using the control circuit, the one or more appliances to execute one or more operations based on the presence of the floating neutral condition.

In accordance with one embodiment, An appliance configured to detect a presence of a floating neutral condition is provided. The appliance comprises a control circuit communicatively connected to a plurality of appliances. The control circuit is configured to instruct each appliance of the plurality of appliances to: record a first set of voltage data corresponding to at least one terminal of an electrical circuit; apply a load on the electrical circuit; record a second set of voltage data corresponding to the at least one terminal after the load is applied; and transmit the first set of voltage data and the second set of voltage data to the control circuit. The control circuit is further configured to: analyze the first set of voltage data and the second set of voltage data to detect a presence of a floating neutral condition; and instruct one or more appliances of the plurality of appliances to execute one or more operations based on the presence of the floating neutral condition.

These and other features, aspects and advantages of the present invention will become better understood with reference to the following description and appended claims. The accompanying drawings, which are incorporated in and constitute a part of this specification, illustrate embodiments of the technology and, together with the description, serve to explain the principles of the technology.

### BRIEF DESCRIPTION OF THE DRAWINGS

A full and enabling disclosure of the present invention, including the best mode of making and using the present systems and methods, directed to one of ordinary skill in the art, is set forth in the specification, which makes reference to the appended figures, in which:

FIG. 1 is an example block diagram of a system for detecting the presence of a floating neutral condition in accordance with embodiments of the present disclosure;

FIG. 2 is an example circuit schematic for a system for detecting the presence of a floating neutral condition in accordance with embodiments of the present disclosure;

FIG. 3 illustrates a flow diagram of an example method for detecting the presence of a floating neutral condition according to example embodiments of the present disclosure;

FIG. 4 illustrates a perspective view of a washing machine appliance according to example embodiments of the present disclosure;

FIG. 5 illustrates another perspective view of a washing machine appliance according to example embodiments of the present disclosure;

FIG. 6 illustrates a cross-sectional view of a washing machine appliance according to example embodiments of the present disclosure; and

FIG. 7 illustrates a flow diagram of an exemplary method for detecting the presence of a floating neutral condition according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments of the present invention, one or more examples of which are illustrated in the drawings. The word “exemplary” is used herein to mean “serving as an example, instance, or illustration.” Any implementation described herein as “exemplary” is not necessarily to be construed as preferred or advantageous over other implementations. Moreover, each example is provided by way of explanation, rather than limitation of, the technology. In fact, it will be apparent to those skilled in the art that modifications and variations can be made in the present technology without departing from the scope or spirit of the claimed technology. For instance, features illustrated or described as part of one embodiment can be used with another embodiment to yield a still further embodiment. Thus, it is intended that the present disclosure covers such modifications and variations as come within the scope of the appended claims and their equivalents. The detailed description uses numerical and letter designations to refer to features in the drawings. Like or similar designations in the drawings and description have been used to refer to like or similar parts of the invention.

As used herein, the terms “first,” “second”, and “third” may be used interchangeably to distinguish one component from another and are not intended to signify location or importance of the individual components. The singular forms “a,” “an,” and “the” include plural references unless the context clearly dictates otherwise. The terms “coupled,” “fixed,” “attached to,” and the like refer to both direct coupling, fixing, or attaching, as well as indirect coupling, fixing, or attaching through one or more intermediate components or features unless otherwise specified herein. As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Terms of approximation, such as “about,” “generally,” “approximately,” or “substantially,” include values within ten percent greater or less than the stated value. When used in the context of an angle or direction, such terms include within ten degrees greater or less than the stated angle or direction. For example, “generally vertical” includes directions within ten degrees of vertical in any direction, e.g., clockwise or counter-clockwise.

Benefits, other advantages, and solutions to problems are described below with regard to specific embodiments. However, the benefits, advantages, solutions to problems, and any feature(s) that may cause any benefit, advantage, or solution to occur or become more pronounced are not to be construed as a critical, required, or essential feature of any or all the claims.

Generally, systems and methods for detecting the presence of a floating neutral condition are disclosed. Systems and methods disclosed herein may be designed to detect the presence of a floating neutral condition within an electrical circuit. The system includes one or more appliances, each electrically connected to corresponding terminals of the circuit. Each appliance is equipped to record at least two sets of voltage data: the first set corresponding to the voltage at one terminal before applying any load, and the second set during loading of the circuit. The appliances then transmit both sets of voltage data to a central control circuit for further analysis.

Systems and methods disclosed herein include a control circuit. The control circuit is configured to receive the voltage data from each device. The control circuit is configured to detect any signs of a floating neutral condition by analyzing the sets of voltage data. This is done by comparing the voltage readings before and after the load is applied, the system can identify abnormalities in the voltage that would suggest the neutral wire is not functioning properly, indicating a floating neutral. The control circuit may be incorporated into any appliance disclosed herein. Alternatively, the control circuit may be a cloud-based computing device or another computing device that is remote from the plurality of appliances.

Based on the detection of a floating neutral condition, the control circuit can initiate corrective actions by executing specific operations on the appliances. These operations may include shutting down affected appliances, issuing warnings via notifications, tripping circuit breakers, adjusting voltage levels to prevent damage or hazards, augmenting one or more functions of the appliances, and the like. The control circuit may also require one or more appliances to operate in a way that ensures balanced loading across each leg of the electrical circuit.

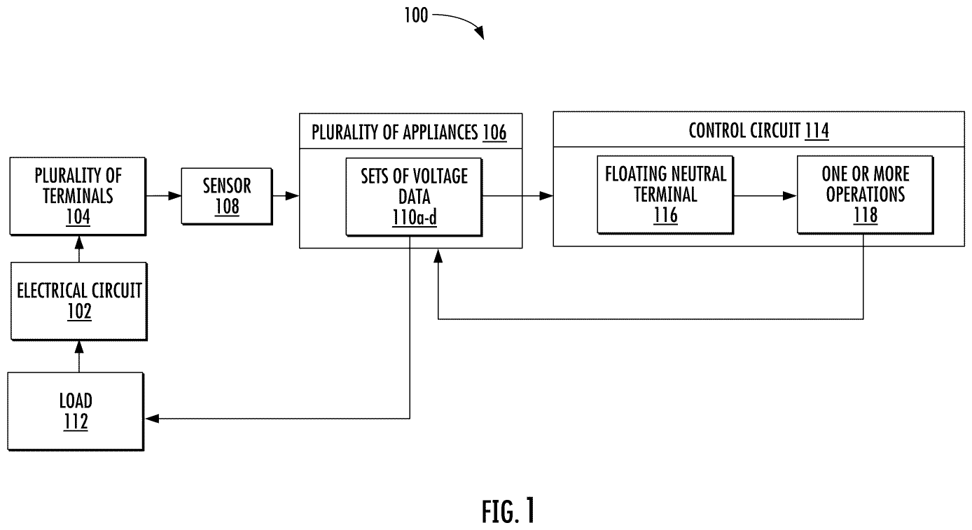

Referring now to FIG. 1, a block diagram of an exemplary system for detecting the presence of a floating neutral condition is shown. As shown in FIG. 1, system 100 may include an electrical circuit 102, a plurality of terminals 104, a plurality of appliances 106, at least a sensor 108, sets of voltage data 110a-d, a load 112, a control circuit 114, floating neutral condition 116, one or more operations 118, and the like.

System 100 may include one or more processors that can be utilized to perform one or more operations. The one or more processors can include any suitable processing device (e.g., a processor core, a microprocessor, an ASIC, a FPGA, a controller, a microcontroller, etc.) and can be one processor or a plurality of processors that are operatively connected. The one or more processors can perform operations in series and/or in parallel. The one or more processors may be dedicated to a particular computing device and/or may be utilized by a plurality of devices to perform processing tasks.

The processor may be designed and/or configured to perform any method, method step, or sequence of method steps in any embodiment described in this disclosure, in any order and with any degree of repetition. For instance, processor may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. This may be used to train, refine, or otherwise improve any algorithm mentioned herein, such as a machine-learning model, a neural network, an algorithm, and the like.

The processor may include a single computing device operating independently or may include two or more computing devices operating in concert, in parallel, sequentially, or the like; two or more computing devices may be included together in a single computing device or in two or more computing devices. Processor may include but is not limited to, for example, a computing device or cluster of computing devices in a first location and a second computing device or cluster of computing devices in a second location. The processor may include one or more computing devices dedicated to data storage, security, distribution of traffic for load balancing, and the like. Processors may distribute one or more operations as described below across a plurality of computing devices, which may operate in parallel, in series, redundantly, or in any other manner used for the distribution of tasks or memory between computing devices.

System 100 may include a memory that can store data and/or instructions. The memory can include one or more non-transitory computer-readable storage mediums, such as RAM, ROM, EEPROM, EPROM, flash memory devices, magnetic disks, etc., and combinations thereof. The data can include user data, application data, operating system data, etc. The data can include voltage data, data associated with a floating neutral terminal, data associated with electrical faults, text data, image data, audio data, statistical data, latent encoding data, etc. The instructions can include instructions that when executed by one or more of the processors may cause system 100 to perform operations as described herein.

Memory may store data and/or instructions associated with one or more applications. The one or more applications can include native, factory-set applications and/or downloaded applications. The applications may include one or more messaging applications, one or more image capture applications, one or more social media applications, one or more productivity applications, one or more map applications, one or more device management applications, one or more browser applications, and the like. In some implementations, the applications can include one or more applications communicatively connected to one or more server computing systems for providing access to a platform.

System 100 includes a plurality of appliances 106 electrically connected to corresponding terminals 104 of an electrical circuit 102. The electrical circuit 102 may represent the electrical system of a residential or commercial structure. The electrical circuit 102 is used to distribute electrical power throughout the structure, such as providing electrical power to a plurality of terminals 104 which are electrically connected to the plurality of appliances 106 or other devices that use electrical power. The design of the electrical circuit 102 may vary depending on the layout and the electrical requirements of the structure. The circuit is typically divided into multiple branches or legs, each providing power to different areas or systems within the structure. For example, one leg may serve the kitchen appliances, another may power the lighting system, and a third could be dedicated to powering outlets in bedrooms or offices. This ensures that the electrical load is balanced and can be managed more effectively.

The terminals 104 are the connections found at power sockets throughout the structure, into which one or more of the appliances 106 can be plugged. When appliance 106 is plugged into a socket, terminals 104 establish a secure electrical connection that allows current to flow from the electrical circuit 102 into the appliance 106. In some cases, one or more of the appliances 106 may be hard wired to the electrical circuit and not connected through a terminal 104.

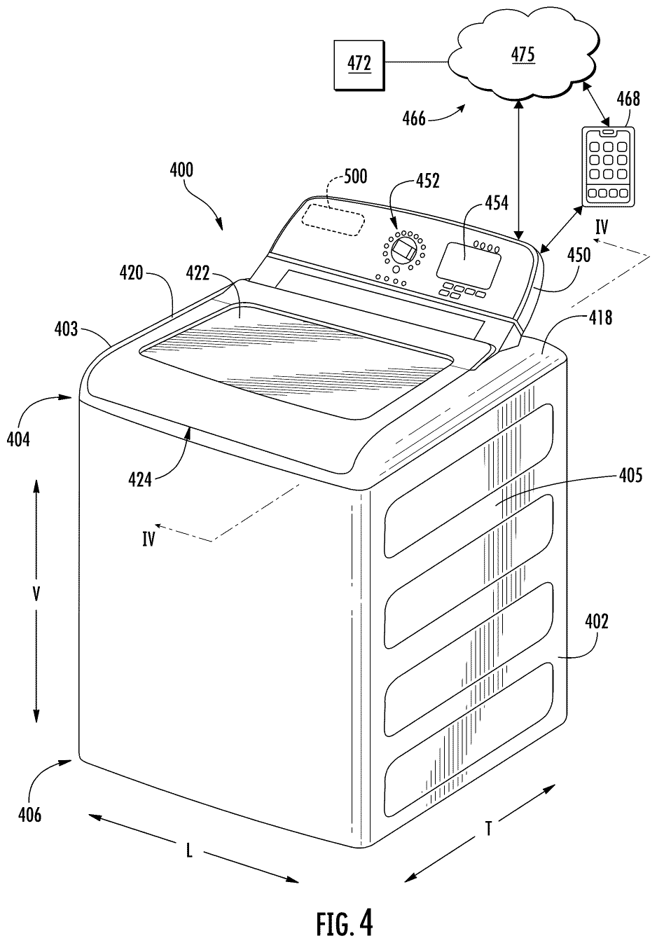

The plurality of appliances 106 refers to an array of household or commercial devices powered by electricity. The plurality of appliances 106 may be the same or substantially similar to any appliance discussed herein, including the appliances discussed herein below in FIGS. 4-6. Those of ordinary skill in the art should understand that the plurality of appliances 106 may include any domestic appliance without deviating from the scope of the present disclosure. These appliances 106 can vary significantly in terms of function, design, and power requirements, but all share a common reliance on electrical energy to operate. For instance, the plurality of appliances 106 may include devices such as refrigerators, microwave ovens, cooktops, ovens, washing machines, dryers, water heaters, water filters, water purifiers, air conditioners, space heaters, heater, HVAC units, and the like. While the examples listed above are typical household appliances, the scope of appliances 106 extends far beyond that, including specialized equipment used in commercial and industrial settings.

In an embodiment, each appliance of the plurality of appliances 106 may include at least a sensor 108 configured to detect voltage data 110a-d associated with the electrical circuit 102. As used in the current disclosure, sensor 108 is an electronic device designed to measure and record voltage data from an electrical circuit. The sensor 108 is designed to monitor or measure specific electrical parameters, such as voltage, current, electrical noise, and the like. In an embodiment, the sensor 108 may be configured to measure the voltage between the line, neutral, and ground terminals or monitor the current flow across them. When connected to the line and neutral terminals, the sensor 108 can track the difference in voltage to record voltage data 110a-d. The sensor 108 could be embedded within an appliance 106 to continuously monitor the properties of the electrical circuit 102.

With continued reference to FIG. 1, each appliance 106 of the plurality of appliances 106 is configured to record one or more sets of voltage data 110a-d corresponding to at least one terminal 104 of the electrical circuit 102. As used in the current disclosure, a set of voltage data 110a-d refers to a collection of electrical measurements taken from one or more appliances within the plurality of appliances 106. This may include taking electrical measurements using each appliance of the plurality of appliances 106. The sets of voltage data 110a-d may be used to capture the electrical conditions at specific points within the system, primarily at terminals 104, where appliances 106 are connected to the electrical circuit 102.

The voltage data 110a-d recorded by each appliance 106 may be associated with the terminal 104, which is directly associated with the appliance 106. This voltage data 110a-d may be used to monitor the voltage that is being supplied to each device by the electrical circuit 102. By measuring the voltage at these terminals 104, system 100 may be configured to detect a plurality of electrical faults, such as voltage dips, surges, floating neutral conditions, and imbalances along with other issues that may affect the appliance's performance or the integrity of the electrical circuit 102.

In an embodiment, the voltage data 110a-d can be captured at various points in time, depending on when the measurements are most relevant. This includes taking voltage readings before, during, or after one or more appliances 106 has placed a load 112 on the electrical circuit 102. Each set of voltage data 110a-d may reflect a series of electrical measurements taken at different stages of an appliance's operation and within the context of its load 112 on the electrical circuit 102. Each set may be used to capture a distinct moment in the system's functionality. Each of the first, second, third, and fourth sets of voltage data 110a-d may be used by the control circuit 114 to determine the presence of a floating neutral condition 116.

In an embodiment, the one or more sets of voltage data 110a-d may include the first set of voltage data 110a. The first set of voltage data 110a may be captured before any appliance 106 begins its operation or places a load 112 on the electrical circuit 102. This first set of voltage data 110a may be used to reflect the baseline voltage levels of the system when no significant load 112 is being applied. It may serve as a reference point for the overall stability of the electrical circuit 102, ensuring that the voltage supplied to the system is within the expected range when the appliances are not actively consuming power.

In a second embodiment, the one or more sets of voltage data 110a-d may include a second set of voltage data 110b. The second set of voltage data 110b may be taken during the operation of a first appliance of the plurality of appliances 106. In this phase, the first appliance may place a load 112 on the electrical circuit 102 by consuming power. The voltage measurements may reflect how the electrical circuit 102 responds to the load 112 introduced by the at least one appliance 106. This second set of voltage data 110b may reflect whether there are any voltage drops, fluctuations, or irregularities in the system that may occur as a result of the power demands placed on the electrical circuit 102.

In some cases, each appliance of the plurality of appliances may individually place load 112 on the electrical circuit 102 during the recording of the second set of voltage data 110b. Additionally or alternatively, one or more appliances that are located on the first leg of the electrical circuit 102 may place the load 112 on the electrical circuit 102 during recording of the second set of voltage data 110b.

In a third embodiment, the one or more sets of voltage data 110a-d may include a third set of voltage data 110c. The third set of voltage data 110c may be generated by selectively engaging or disengaging the first appliance from the electrical circuit 102 while simultaneously engaging a second appliance that is connected to the circuit. Engaging or disengaging an appliance may include engaging or disengaging one or more components of the appliance such as a motor, heating coil, pump, valves, and any other component mentioned herein. The third set of voltage data 110c may be used to identify the effects of activating or deactivating a specific appliance on the overall system when other appliances are still in operation. To generate the third set of voltage data 110c, the first appliance is either turned on or off, effectively placing a load 112 on or removing it from the electrical circuit 102. Meanwhile, the second appliance is active and continues to draw power from the electrical circuit 102. The third set of voltage data 110c captures the changes in voltage at terminal 104, reflecting how the system responds to the load 112 adjustment caused by the engagement or disengagement of the first appliance.

In a fourth embodiment, the one or more sets of voltage data 110a-d may include a fourth set of voltage data 110d. The fourth set of voltage data 110d may be recorded after an appliance has completed its operation or when the load 112 has been removed from the electrical circuit 102.

The terms first appliance, second appliance, third appliance, and the like may be used interchangeably to refer to any appliance or group of appliances within the plurality of appliances 106. These designations are not fixed to specific devices but rather serve as placeholders for any individual appliance or combination of appliances that may be connected to the electrical circuit 102. This may include appliances that are located on the same or alternating legs of the electrical circuit 102.

With continued reference to FIG. 1, each appliance may be configured to transmit the sets of voltage data 110a-d to a control circuit 114. Each appliance may be equipped with the capability to monitor and transmit voltage data to the control circuit 114. This transmission can occur through wired or wireless communication protocols, depending on the design of the system. The control circuit 114 may act as the central processing unit for the data, aggregating, processing, and evaluating the voltage information from each appliance and analyzing the real-time conditions of the electrical circuit 102. In an embodiment, each appliance may be configured to transmit sets of voltage data 110a-d using an external communication system as discussed herein below in FIGS. 4-6.

With continued reference to FIG. 1, the system includes a control circuit 114 associated with appliance 106. As used in the current disclosure, the control circuit 114 is an electronic system designed to manage, regulate, and monitor the operations 120 of each appliance of the plurality of appliances 106. This may be done by processing signals from various sensors, controls, and other components. The control circuit 114 may include any processor, computing device, remote computing device, and the like mentioned herein. The control circuit 114 may be configured to receive inputs, make decisions based on predefined parameters or algorithms, and then activate or deactivate specific functions or equipment within the appliance 106. In an embodiment, the control circuit 114 may be located within at least one appliance of the plurality of appliance 106. Alternatively, the control circuit 114 may include but is not limited to, for example, a computing device or cluster of computing devices that are remote from system 100, such as a remote server or cloud-based computing system. The control circuit 114 may be consistent with any processor, computing device, and the like discussed within this disclosure.

With continued reference to FIG. 1, the control circuit 114 is configured to analyze the sets of voltage data 110a-d to detect the presence of a floating neutral condition 116 within the electrical circuit 102. As used in the current disclosure, a floating neutral condition 116 refers to a condition of the electrical circuit 102 where the neutral wire is not properly connected to the ground or is disconnected within the circuit. When the neutral wire is “floating,” it can create an unstable electrical environment, potentially causing voltage fluctuations, imbalanced currents, and unpredictable behavior in appliances connected to the system. Issues related to floating neutral condition 116 can lead to malfunctions or permanent damage to any equipment or appliance connected to the electrical circuit 102.

In electrical circuit 102, the floating neutral condition 116 may affect the overall functioning of the system. Normally, the neutral wire should provide a stable reference point for the electrical current, helping maintain consistent voltage across all appliances. However, when the neutral connection becomes loose, broken, or improperly connected, it can result in an unstable electrical environment. The circuit may exhibit voltage imbalances leading to erratic behavior of electrical appliances and the risk of damage to sensitive components.

When comparing the sets of voltage data 110a-d, the control circuit 114 may look for signs of irregularities in the voltage readings that could indicate a floating neutral condition 116 as compared to the baseline measurements. The control circuit 114 may identify the presence of the floating neutral condition 116 when the voltages become unstable. This instability may be reflected by voltage drops or spikes that are not typical for the specific appliances in operation. For example, when an appliance draws current, the voltage in the system may fluctuate unpredictably if the neutral connection is faulty. The control circuit 114 compares these fluctuations against the expected behavior of the system, using the first set of voltage data 110a as a reference.

The control circuit 114 may be configured to identify voltage imbalances that occur across multiple appliances when detecting the presence of a floating neutral condition 116. The comparison of the voltage data may reveal that some appliances are receiving too high or too low a voltage, depending on their position within the circuit, due to the floating neutral condition 116. If these anomalies are detected, control circuit 114 can interpret this as an indication of the floating neutral condition. Additionally, the appliances may experience erratic performance, such as failing to operate properly, intermittent power surges, or shutdowns, which further confirms the presence of the issue.

With continued reference to FIG. 1, the control circuit 114 may further be configured to label each appliance of the plurality of appliances according to its corresponding electrical leg of the electrical circuit based on the first set of voltage data and the second set of voltage data. As used in the current disclosure, the term electrical leg refers to the distinct pathways through which electricity flows from the power source to various appliances on the electrical circuit 102. The electrical circuit 102 may be divided into multiple legs or branches, each of which serves different parts of a structure or powers different appliances.

The control circuit 114 may be configured to label each appliance of the plurality of appliances 106 according to the specific electrical leg of the circuit to which it is connected. By analyzing the sets of voltage data 110a-d, the control circuit 114 can determine which leg each appliance is on by observing how the voltage behaves at the appliance's terminal 104.

When the first set of voltage data 110a is taken, the voltage should be consistent across all appliances connected to the same leg of the circuit, with a standard voltage level defined by the electrical utility (e.g., 120V in a typical U.S. residential setup). If any appliance is connected to a different electrical leg, the voltage readings at its terminal 104 may differ, allowing the control circuit 114 to distinguish between the two legs.

The control circuit 114 may be configured to compare the voltage fluctuations across multiple appliances to identify their location on the electrical legs. Appliances on the same leg will experience similar voltage behaviors, while those on different legs will show differences due to their connection to either the live or neutral leg of the circuit. Each set of voltage data 110a-d may be used by the control circuit 114 to analyze how each appliance affects the overall voltage and determine whether they are part of the same electrical leg.

By labeling appliances according to their electrical leg and analyzing the voltage data 110a-d, the control circuit 114 can track the patterns of voltage data 110a-d across each leg of the electrical circuit 102. For example, if voltage imbalances are detected between appliances on the neutral leg, the control circuit 114 may flag this as an indication of a floating neutral. This identification occurs when voltage measurements for appliances connected to the neutral leg are inconsistent with the baseline readings from appliances on the live leg, revealing that the neutral connection is unstable or broken. Moreover, labeling the appliances can help pinpoint which specific appliances are affected by the floating neutral condition. By tracking how voltage changes across different legs, the control circuit 114 can determine whether the floating neutral is localized to certain appliances or affects multiple appliances across the entire circuit.

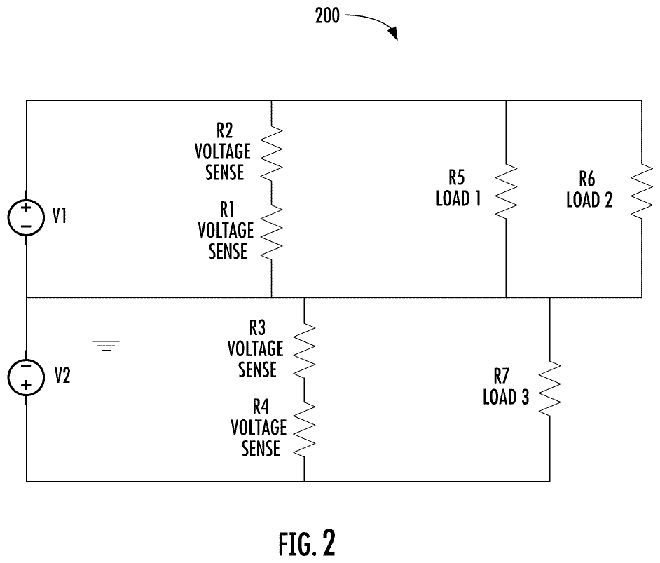

Referring now to FIG. 2, an exemplary circuit schematic for a system for detecting the presence of a floating neutral terminal is shown. Circuit 200 as depicted in FIG. 2, is described in reference to system 100 for detecting the presence of a floating neutral terminal in FIG. 1, those of ordinary skill in the art will understand that circuit 200 may be implemented in any system for detecting a floating neutral terminal. The provided circuit diagram 200 represents a system for detecting the presence of a floating neutral terminal using a plurality of appliances. The circuit 200 may employ a combination of voltage sources, resistors acting as voltage sensors, one or more motors, and one or more coils. Circuit 200 may be used to facilitate the detection of the presence of a floating neutral terminal via monitoring of voltage variations across different terminals 104 and transmitting the recorded data to the control circuit 114.

Circuit 200 includes at least two voltage sources, labeled as V1 and V2, which provide power to the system. V1 and V2 may be part of the electrical circuit 102 as described hereinabove. Those of ordinary skill in the art will understand that although circuit 200 only depicts V1 and V2, circuit 200 may include additional voltage sources, such as V3, V4, up to and including VN.

Circuit 200 may include a plurality of resistors, which serve as voltage-sensing elements. These voltage-sensing elements may be the same or substantially similar to the sensors 108 that are associated with each appliance 106. The resistors R1, R2, R3, and R4 may be used to measure and detect voltage data 110a-d at different points in the circuit.

Additionally, circuit 200 may include one or more loads 1-3 (R5, R6 and R7). The loads 1-3 may represent one or more appliances 106 within the system, drawing current and responding to voltage fluctuations. One or more of the loads may be used to place inductive loads on the circuit, which can be produced by one or more appliances of the plurality of appliances 106. The voltage-sensing elements may be configured to monitor voltage changes when different loads are applied. Specifically, when a decrease in L1 voltage is detected along with an increase in L2 voltage while placing load on the circuit using Load 1, the system can flag a potential floating neutral condition.

The control circuit 114 may be used to determine the presence of a floating neutral condition by selectively turning on a load (e.g. R5, R6, and/or R7) with no other loads applied. If the L1 voltage increases while L2 voltage decreases, this provides additional confirmation of the floating neutral state.

With continued reference to FIG. 2, the control circuit 114 may be used to determine which leg of the electrical circuit 102 an appliance using voltage-sensing resistors (R1, R2, R3, and R4). Each of these resistors may be positioned to measure the voltage at different points in the circuit relative to a common reference, typically neutral. When an appliance is activated, the voltage-sensing elements may be configured to monitor voltage changes when different loads are applied. Specifically, when a decrease in L1 voltage is detected along with an increase in L2 voltage while running the motor, the system can flag a potential floating neutral condition by detecting changes in voltage at specific terminals. By comparing the voltage values recorded at these resistors before and after a load is applied, the system can determine whether the appliance is on L1 or L2 based on the observed voltage shifts. If an appliance is on L1, its activation will cause a change in the voltage profile at the sensors associated with L1 while having minimal impact on the sensors associated with L2, and vice versa.

A floating neutral may be determined by analyzing how voltage data 110a-d responds to changes in load distribution between L1 and L2. Under normal circumstances, activating an appliance on L1 should result in a predictable drop in L1 voltage with little or no effect on L2 voltage, while activating an appliance on L2 should cause a drop in L2 voltage with minimal effect on L1 voltage. However, when the neutral connection is floating, a load applied to L1 can cause an increase in L2 voltage, and vice versa. This is because, without a proper neutral reference, the voltage potential between L1 and L2 becomes imbalanced, causing fluctuations across the entire circuit instead of remaining isolated to a single leg. By monitoring these inverse voltage changes when switching on one or more of the loads 1-3 independently, the system can confirm the presence of a floating neutral. Furthermore, if the load 1 and load 3 are equivalent loads, turning them on simultaneously should maintain a stable L1/L2/N relationship in a properly functioning system, whereas an unstable or shifting voltage would indicate a floating neutral condition.

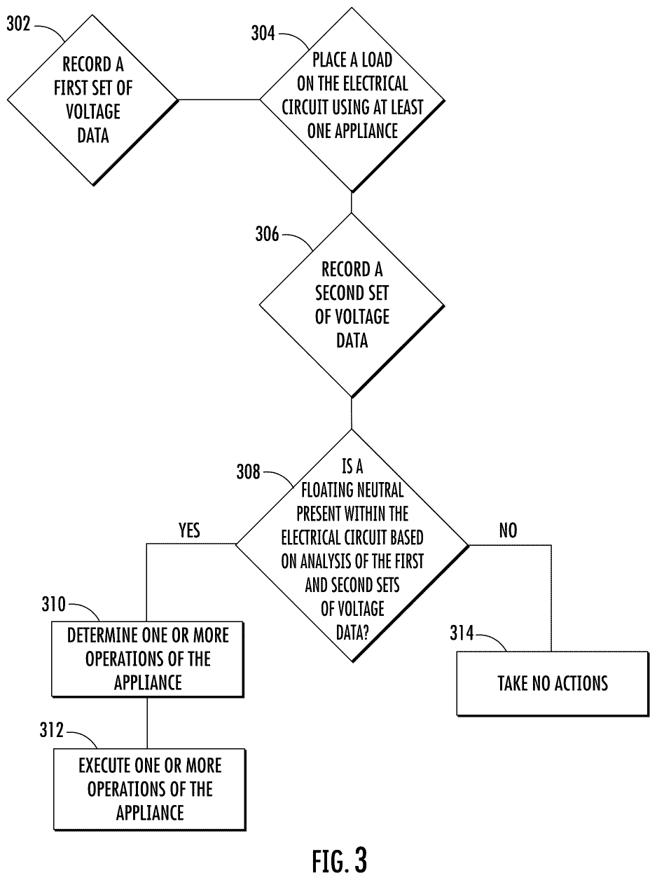

Referring now to FIG. 3, a flowchart of method 300 for detecting the presence of a floating neutral condition is illustrated. Although method 300 is described in the context of system 100 as shown in FIG. 1, it will be understood by those skilled in the art that method 300 can be implemented using any suitable system for detecting the presence of a floating neutral condition. Furthermore, this method can be applied to a variety of appliances, including but not limited to a refrigerator, dishwasher, microwave oven, cooktop, washing machine, dryer, water heater, water filter, water purifier, air conditioner, space heater, and the like as illustrated in FIGS. 4-6.

At operation 302, method 300 includes recording a first set of voltage data 110a using the plurality of appliances 106. As previously described in reference to FIG. 1, recording the first set of voltage data 110a may be achieved by recording the voltage data 110a at various terminals 104 throughout the electrical circuit 102 using sensors 108 within the plurality of appliances 106.

At operation 304, method 300 includes placing a load upon the electrical circuit 102. This may be done using any method or combination of methods disclosed herein.

At operation 306, method 300 includes recording the second set of voltage data 110b. The second set of voltage data 110b may be taken during the operation of one or more appliances of the plurality of appliances 106. These appliances may be on the same or alternating legs of the electrical circuit 102. In this phase, at least one appliance may place a load 112 on the electrical circuit 102 by consuming power. In some cases, appliances may alternate placing load 112 on the electrical circuit while recording the second set of voltage data 110b.

At operation 308, the control circuit 114 decides if a floating neutral condition 116 is present within the electrical circuit 102 based on analysis of the first and second sets of voltage data 110a-b. This determination may be made by identifying discrepancies between the voltage levels recorded before and after the load 112 was applied. Specifically, the control circuit 114 may analyze variations in voltage stability across different terminals 104 to detect abnormal fluctuations or imbalances indicative of a floating neutral condition 116. If significant deviations beyond an acceptable threshold are detected, the control circuit 114 may classify the circuit as having a floating neutral condition 116. If the floating neutral condition 116 is identified, the process continues to operation 310. Otherwise, the method proceeds to operation 314, where no action is taken, and the appliance runs normally.

At operation 310, method 300 includes determining one or more operations 118 of the appliance based on the floating neutral condition 116. The control circuit 114 may be used to determine the appropriate corrective actions. This may involve modifying, adjusting, or altering the operation of one or more components of the appliances 106 to mitigate the impact of the detected floating neutral condition 116. This adjustment could include altering the functionality of various components or systems within the appliance, as described in greater detail in FIGS. 4-6.

In some cases, the one or more operations 118 may include adjusting one or more functions of the appliance 106 to compensate for voltage instability. This may include modifying power consumption, altering operational parameters, or temporarily disabling certain components to reduce the risk of damage.

In another embodiment, one or more operations 118 may include tripping circuit breakers, effectively disconnecting power to the affected section of the electrical circuit 102 to prevent overheating, electrical arcing, or equipment failure.

In some cases, one or more operations 118 may include selectively disconnecting an affected leg of the electrical circuit 102 to isolate the fault while allowing unaffected sections to continue operation. This approach may help maintain functionality for unaffected appliances while addressing the floating neutral condition.

At operation 312, based on the determination made in operation 310, control circuit 114 may execute the necessary operations to modify the appliance's behavior. These operations 118 may be designed to ensure that the appliances continue to operate efficiently while minimizing interference.

At operation 314, if the floating neutral condition 116 is not detected in operation 308, the system will take no corrective action and will allow the plurality of appliances 106 to continue operating as usual without interruption.

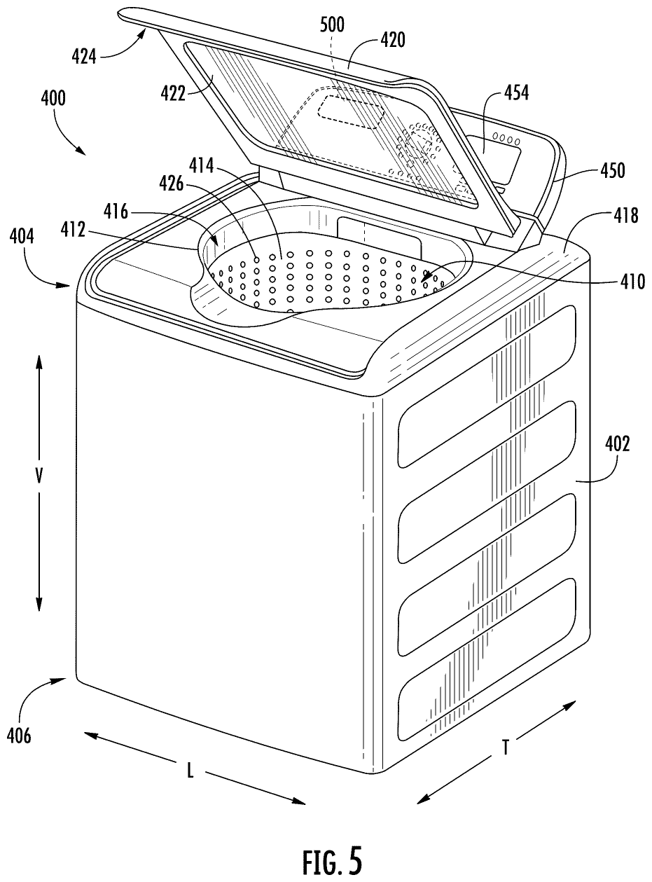

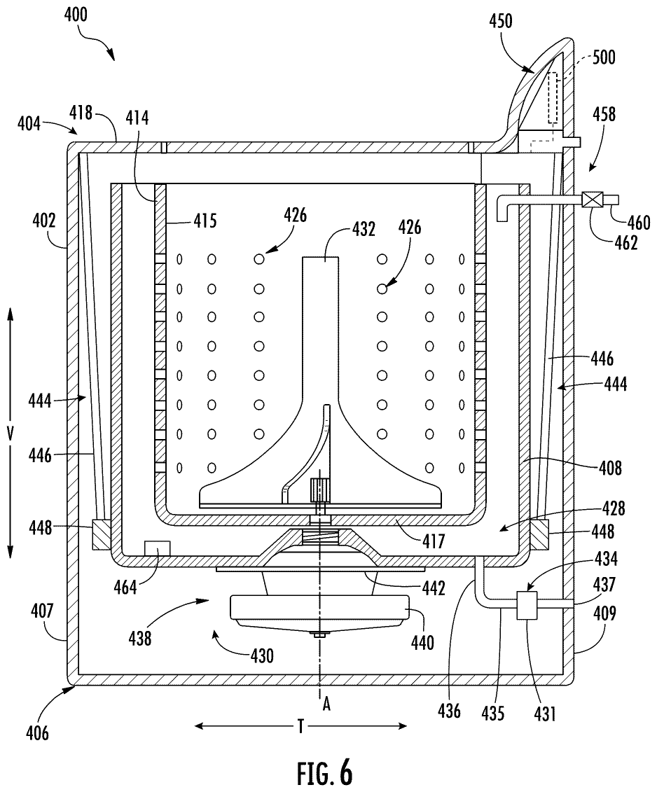

Referring to the FIGS. 4-6, an example illustration of washing machine appliance 400. Specifically, FIGS. 4 and 5 illustrate perspective views of washing machine appliance 400 with the lid in a closed and an open position, respectively. FIG. 6 provides a side cross-sectional view of washing machine appliance 400. Washing machine appliance 400 generally defines a vertical direction V, a lateral direction L, and a transverse direction T, each of which is mutually perpendicular, such that an orthogonal coordinate system is generally defined.

Washing machine appliance 400 may be the same or substantially similar to appliance 106. While appliance 400 may depicted as a washing appliance (e.g., washing machine or dryer), those of ordinary skill in the art will understand that any domestic appliance may be used without deviating from the scope of the present disclosure. For example, appliances may include a refrigerator, a dishwasher, a microwave oven, a cooktop, an oven, a washing machine, a dryer, a water heater, a water filter or purifier, an air conditioner, a space heater, or any other household appliance which performs similar functions.

As shown in FIGS. 4 through 6, washing machine appliance 400 is depicted with an axis of rotation A that is substantially parallel to the vertical direction V. In this regard, washing machine appliance 400 is generally referred to as a “vertical axis” or top loading washing machine appliance 400. However, it will be understood that aspects of the present disclosure may be used within the context of any suitable washing machine appliance, such as a horizontal axis or front loading washing machine appliance. Furthermore, one of ordinary skill in the art will understand that modifications and variations may be made to washing machine appliance 400 (e.g., vertical axis washing machine appliance 400), including different configurations, different appearances, or different features while remaining within the scope of the present disclosure.

As shown in FIG. 4, washing machine appliance 400 may include a cabinet 402 that extends between a top portion 404 and a bottom portion 406 along the vertical direction V, between a first (left) side panel 403 and a second (right) side panel 405 along the lateral direction L, and between a front panel 407 and a rear panel 409 along the transverse direction T. As shown in FIG. 6, a wash tub 408 is positioned within cabinet 402, the wash tub 408 defining a wash chamber 410, and generally configured for retaining wash fluids during an operating cycle. As used herein, “wash fluid” means water, or water with additives (for example detergent, fabric softener, or bleach) used in any part of a laundry appliance operation or cycle. Without limitation, “wash fluid” includes fluid used in wash, rinse, or drain and spin cycles.

Further, washing machine appliance 400 may include a wash basket 414 positioned within wash tub 408 and generally defining an opening 416 for receipt of laundry articles for washing. Wash basket 414 may be defined by a side wall 415 and a bottom wall 417 with side wall 415 and bottom wall 417 defining a wash chamber 410. Wash basket 414 may be supported within wash tub 408 for rotation about an axis of rotation A. According to the illustrated embodiment, the axis of rotation A may be substantially parallel to the vertical direction V and runs through the center of the wash tub 408 and wash basket 414. In this regard, washing machine appliance 400 is generally referred to as a “vertical axis” or top loading washing machine appliance 400.

As illustrated, cabinet 402 of washing machine appliance 400 has a top panel 418 which defines a top panel opening 412 (FIG. 5) that coincides with opening 416 of wash basket 414 to permit a user access to wash basket 414. Washing machine appliance 400 may further include a lid 420 which may be rotatably mounted to top panel 418 to permit selective access to wash basket 414 through opening 416. Lid 420 selectively rotates between the closed position (FIG. 4) and the open position (FIG. 5). In the closed position, lid 420 blocks access to wash basket 414. Conversely, in the open position, a user can access wash basket 414. A window 422 in lid 420 permits viewing of wash basket 414 when lid 420 is in the closed position, for example, during operation of washing machine appliance 400. Lid 420 may also include a handle 424 that may facilitate opening and closing lid 420. Further, although lid 420 is illustrated as mounted to top panel 418, lid 420 may alternatively be mounted to cabinet 402 or any other suitable support.

As illustrated in FIGS. 5 and 6, wash basket 414 may further define a plurality of perforations 426 formed inside wall 415 to facilitate fluid communication between an interior of wash basket 414 and wash tub 408. For at least this purpose, wash basket 414 is spaced apart from wash tub 408 to define a space for wash fluid to escape wash chamber 410. During a spin cycle, wash fluid within articles of clothing and within wash chamber 410 may be urged through perforations 426 and may collect in a sump 428 defined between the lower portions of wash basket 414 and wash tub 408. Washing machine appliance 400 may further include a pump assembly 434 (FIG. 6) that is located beneath wash tub 408 and wash basket 414 for gravity assisted flow when draining wash tub 408. Pump assembly may include a drain pump 431 and associated conduit or tubing 435 to couple the drain pump to the wash tub 408 and to the external environment, for example an external drain (not shown). The first end 436 of tubing 435 may fluidly couple pump assembly 434 to the wash tub 408, for example at sump 428, to facilitate removal of wash fluid. Second end 437 of tubing 435 may be fluidly coupled to an external drain (not shown) to accept effluent from the wash tub 408. Drain pump 431 may be operably coupled to control circuit 500 to accept operating instructions (for example on or off commands or speed control) to drain wash fluid from wash tub 408 and provide feedback to the control circuit 500.

In some embodiments, an impeller or agitation element 432 (FIG. 6), such as a vane agitator, may be disposed in wash basket 414 to impart an oscillatory motion to laundry articles and liquid in wash basket 414. More specifically, agitation element 432 extends into wash basket 414 and assists agitation of articles disposed within wash basket 414 during operation of washing machine appliance 400 to, for example, facilitate improved cleaning. In different embodiments, agitation element 432 includes a single action element (i.e., oscillatory only), a double action element (oscillatory movement at one end, single direction rotation at the other end) or a triple action element (oscillatory movement plus single direction rotation at one end, single direction rotation at the other end). As illustrated in FIG. 6, agitation element 432 and wash basket 414 are oriented to rotate about axis of rotation A, which is substantially parallel to vertical direction V and centrally located in wash tub 408.

As illustrated in FIG. 6, washing machine appliance 400 includes a motor assembly 438 in mechanical communication with (i.e., mechanically coupled to) wash basket 414 and agitation element 432 (if present) to selectively rotate wash basket 414, for example during an agitation or a rinse cycle of washing machine appliance 400. In addition, motor assembly 438 may also be in mechanical communication with agitation element 432. In this manner, motor assembly 438 may be configured for selectively rotating or oscillating wash basket 414 and/or agitation element 432 during various operating cycles of washing machine appliance 400.

Motor assembly 438 may generally include one or more of a drive motor 440 and a transmission assembly 442, for example a clutch assembly for engaging and disengaging wash basket 414 and/or agitation element 432 with the drive motor 440. The drive motor 440 may be a brushless DC electrical motor, e.g., a pancake motor as illustrated. However, according to alternative embodiments, drive motor 440 may be any other suitable type or configuration of motor. For example, drive motor 440 may be an AC motor, an induction motor, a permanent magnet synchronous motor, or any other suitable type of motor. In addition, motor assembly 438 may include any other suitable number, types, and configurations of support bearings or drive mechanisms. Generally, the motor assembly 438 is fixed to the wash tub 408 with appropriate sealing elements (not shown) to achieve a watertight seal to contain wash fluid in the wash tub 408.

The components of washing machine appliance 400 suspended from cabinet 402 may be collectively defined as a subwasher 430 of washing machine appliance 400. For example, subwasher 430 may include the wash tub 408, the wash basket 414, and the motor assembly 438.

The subwasher 430 may be suspended from the cabinet 402 and supported by a vibration damping suspension system. The damping suspension system operates to damp dynamic motion as the wash basket 414 rotates within the tub 408, for example during a spin cycle. The damping suspension system can include one or more suspension assemblies 444 coupled between and to the cabinet 402 and subwasher 430. Generally, the suspension assemblies 444 comprise a suspension rod 446 and a spring damper 448. Typically, four suspension assemblies 444 are utilized, and are spaced apart about the subwasher 430. In the illustrative example of FIG. 6, four suspension assemblies 444 are provided, two are visible in the figure and two are hidden by the visible suspension assemblies 444.

The suspension assemblies 444 may be distributed around the subwasher 430 in any suitable manner to provide support and motion damping to the subwasher 430. For example, each suspension assembly 444 may be rotatably attached at one end proximate a corner of the cabinet 402. At an opposite end, the suspension assembly 444 may be rotatably attached to the subwasher 430 as illustrated. In other embodiments, the suspension assemblies 444 may be rotatably attached to the cabinet 402 and subwasher 430 in other locations. In the example embodiment of FIG. 6, the spring damper 448 is disposed between the subwasher 430 and the suspension rod 446. In other embodiments, the spring damper 448 may be disposed between the cabinet 402 and the suspension rod 446. In still other embodiments, the spring damper 448 may be disposed in other locations along the length of the suspension rod 446.

Referring still to FIGS. 4 through 6, washing machine appliance 400 further includes a control panel 450. As shown, control panel 450 may extend from top panel 418 of washing machine appliance 400. Control panel 450 may include one or more input selector 452 (e.g., a user interface input) for operator selection of machine cycles and features. A display 454 of control panel 450 may indicate selected features, operation mode, a countdown timer, and/or other items of interest to appliance users regarding operation.

Control panel 450 further includes control circuit 500. Operation of washing machine appliance 400 is controlled by control circuit 500 that is operatively coupled (e.g., electrically coupled or connected) to at least one user input selector 452 located on control panel 450 (FIG. 4) for user manipulation to select washing machine cycles and features. Control panel 450 and input selector 452 collectively form a user interface input for operator selection of machine cycles and features. In response to user manipulation of the user input selector 452, control circuit 500 operates the various components of washing machine appliance 400 to execute selected machine cycles and features. A display 454 on control panel 450 may indicate selected features, operation mode, a countdown timer, and/or other items of interest to appliance users regarding operation. In addition to the visual display 454, control panel 450 may also include auditory signaling devices, such as a speaker.

Washing machine appliance 400 may receive power from a power supply, such as a residential power outlet or other power source. For example, the power supply may provide conventional 60 Hz, 120-volt or 240-volt AC to washing machine appliance 400. The power supply may also include an earth ground path operatively coupling the power supply to earth ground. As such, washing machine appliance 400 includes an earth ground input configured to operatively connect to earth ground (e.g., via the earth ground path of the power supply). In some embodiments, control panel 450 may include the earth ground input. In such an embodiment, control circuit 500 may be operatively coupled to the earth ground input.

The control circuit 500 may be operably coupled to a wash fluid supply assembly 458 to supply wash fluid to the wash tub 408. Wash fluid supply assembly may include a water supply 460, for example from a municipal water source, a valve 462, and associated piping. The valve 462 may be operably coupled to the control circuit 500 to open and close as needed to supply wash water to the wash tub 408. The wash fluid supply assembly 458 may also be fluidly coupled to dispensers (not shown) for detergent, bleach, or other water treatments that may be combined with the supplied water to produce a wash fluid. The dispensers maty be operably coupled to the control circuit 500 to selectively introduce water treatments to the water in producing wash fluid.

A sensor 464, for example a pressure sensor, may be provided in the wash tub 408 to sense the amount of wash fluid present in the tub 408. The sensor may be operably coupled to the control circuit 500 and send a signal corresponding to the pressure of the water within the tub 408. Accordingly, sensor 464 may be located at or close to the bottom of tub 408. The pressure signal may be converted to a wash fluid depth at the sensor 464 and transmitted to the control circuit 500 or it may be sent to the control circuit 500 for processing and converting into a wash fluid depth. Determining the depth of wash fluid may be useful in determining when the wash basket 414 has received a sufficient amount (or total amount) of wash fluid to properly process a laundry load. Determining the wash fluid depth may also be useful in operating the washing machine appliance 400 during various cycles, such as during a spin cycle. To maintain a proper amount of wash fluid in wash tub 408, the control circuit 500 may selectively operate the drain pump 431 to an on or an off condition in response to a sensor signal from the sensor 464.

Components of washing machine appliance 400 may be in operative communication with control circuit 500 via one or more signal lines or shared communication busses to provide signals to and/or receive signals from the control circuit 500. For example, the control circuit 500 may communicate with the motor assembly 438 to selectively rotate the wash basket 414 at various speeds or directions of rotation.

In some embodiments, washing machine appliance 400 may include an external communication system 466. Referring back to FIG. 4, a schematic illustration of an external communication system 466 will be described according to an example embodiment of the present subject matter. In general, external communication system 466 is configured for permitting interaction, data transfer, and other communications between washing machine appliance 400 and one or more external devices. For example, this communication may be used to provide and receive operating parameters, user instructions or notifications, performance characteristics, user preferences, or any other suitable information for improved performance of washing machine appliance 400. In addition, it should be appreciated that external communication system 466 may be used to transfer data or other information to improve performance of one or more external devices or appliances and/or improve user interaction with such devices.

For example, external communication system 466 permits control circuit 500 of washing machine appliance 400 to communicate with a separate device external to washing machine appliance 400, referred to generally herein as an external device 468. As described in more detail below, these communications may be facilitated using a wired or wireless connection, such as via a network 475. In general, external device 468 may be any suitable device separate from washing machine appliance 400 that is configured to provide and/or receive communications, information, data, or commands from a user. In this regard, external device 468 may be, for example, a personal phone, a smartphone, a tablet, a laptop or personal computer, a wearable device, a smart home system, or another mobile or remote device.

In addition, a remote server 472 may be in communication with washing machine appliance 400 and/or external device 468 through network 475. In this regard, for example, remote server 472 may be a cloud-based server, and is thus located at a distant location, such as in a separate state, country, etc. According to an example embodiment, external device 468 may communicate with a remote server 472 over network 475, such as the Internet, to transmit/receive data or information, provide user inputs, receive user notifications or instructions, interact with or control washing machine appliance 400, etc. In addition, external device 468 and remote server 472 may communicate with washing machine appliance 400 to communicate similar information.

In general, communication between washing machine appliance 400, external device 468, remote server 472, and/or other user devices or appliances may be carried using any type of wired or wireless connection and using any suitable type of communication network, non-limiting examples of which are provided below. For example, external device 468 may be in direct or indirect communication with washing machine appliance 400 through any suitable wired or wireless communication connections or interfaces, such as network 475. For example, network 475 may include one or more of a local area network (LAN), a wide area network (WAN), a personal area network (PAN), the Internet, a cellular network, any other suitable short-or long-range wireless networks, etc. In addition, communications may be transmitted using any suitable communications devices or protocols, such as via Wi-Fi®, Bluetooth®, Zigbee®, wireless radio, laser, infrared, Ethernet type devices and interfaces, etc. In addition, such communication may use a variety of communication protocols (e.g., TCP/IP, HTTP, SMTP, FTP), encodings or formats (e.g., HTML, XML), and/or protection schemes (e.g., VPN, secure HTTP, SSL).

External communication system 466 is described herein according to an example embodiment of the present subject matter. However, it should be appreciated that the example functions and configurations of external communication system 466 provided herein are used only as examples to facilitate description of aspects of the present subject matter. System configurations may vary, other communication devices may be used to communicate directly or indirectly with one or more associated appliances, other communication protocols and steps may be implemented, etc. These variations and modifications are contemplated as within the scope of the present subject matter.

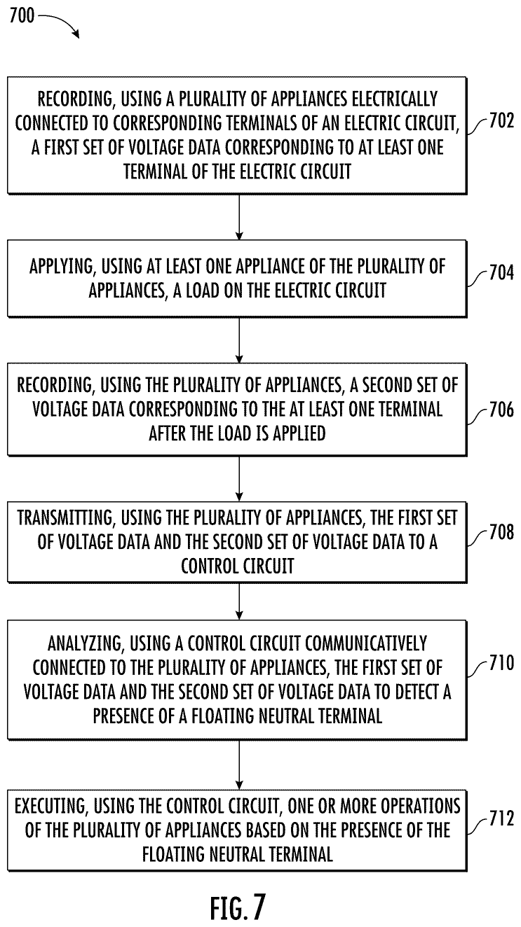

Referring now to FIG. 7, an example flow diagram for a method detecting the presence of a floating neutral condition.

At operation 702, the method includes instructing, using a control circuit, one or more appliances to record a first set of voltage data corresponding to at least one terminal of an electrical circuit, wherein the one or more appliances are electrically connected to corresponding terminals of the electrical circuit in accordance with embodiments of the present disclosure.

At operation 704, the method includes instructing, using the control circuit, the one or more appliances to apply a load on the electrical circuit in accordance with embodiments of the present disclosure.

At operation 706, the method includes instructing, using the control circuit, the one or more appliances to record a second set of voltage data corresponding to the at least one terminal after the load is applied in accordance with embodiments of the present disclosure.

At operation 708, the method includes instructing, using the control circuit, the one or more appliances to transmit the first set of voltage data and the second set of voltage data to the control circuit in accordance with embodiments of the present disclosure.

At operation 710, the method includes analyzing, using the control circuit, the first set of voltage data and the second set of voltage data to detect a presence of a floating neutral condition; in accordance with embodiments of the present disclosure.

At operation 712, the method includes instructing, using the control circuit, the one or more appliances to execute one or more operations based on the presence of the floating neutral condition in accordance with embodiments of the present disclosure. The one or more operations may include generating a notification when it detects the presence of the floating neutral condition. This notification may serve as an early warning to prevent further damage to appliances or the circuit. In some cases, The generated notification can be displayed on a user interface linked to a user device, such as a smartphone, tablet, or computer. Additionally or alternatively, the notification can be shown through a graphical user interface (GUI) that is directly associated with one or more appliances in the system. This GUI displays the notification on the appliance's control panel or screen.

In an embodiment, the one or more operations may include modifying the functionality of an appliance when the floating neutral condition is detected. This could involve adjusting settings or switching off certain features to prevent further damage or unsafe operation. Modifying the appliance's operation may be done to help protect both the device and the overall system from the hazards of an unstable electrical connection.

In an additional embodiment, the one or more operations may include recording an internal fault for the appliance based on the floating neutral condition. By logging the fault, the system can track and document the issue for future reference or troubleshooting. This recorded fault may be transmitted to a user device or displayed on a graphical user interface.

The method may additionally include using the control circuit to assign a label to each appliance, identifying its specific electrical leg in the circuit. This labeling may be done to determine how each appliance is connected to the overall electrical system. By doing so, the control circuit enhances the ability to pinpoint which appliance or electrical leg is affected by the floating neutral condition.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

What is claimed is:

1. A system for detecting a presence of a floating neutral condition, the system comprising:
a control circuit communicatively connected to one or more appliances, wherein the one or more appliances are electrically connected to corresponding terminals of an electrical circuit, wherein the control circuit is configured to instruct the one or more appliances to:
record a first set of voltage data corresponding to at least one terminal of the electrical circuit;
apply a load on the electrical circuit;
record a second set of voltage data corresponding to the at least one terminal after the load is applied; and
transmit the first set of voltage data and the second set of voltage data to the control circuit; and
the control circuit is further configured to:
analyze the first set of voltage data and the second set of voltage data to detect a presence of a floating neutral condition; and
instruct the one or more appliances to execute one or more operations based on the presence of the floating neutral condition.

2. The system of claim 1, wherein the control circuit is further configured to label the one or more appliances according to its corresponding electrical leg of the electrical circuit based the first set of voltage data and the second set of voltage data.

3. The system of claim 1, wherein the one or more operations comprises generating a notification based on the presence of the floating neutral condition.

4. The system of claim 3, wherein generating the notification comprises transmitting the notification to a user interface associated with a user device.

5. The system of claim 3, wherein generating the notification comprises displaying the notification using a graphical user interface associated with the one or more appliances.

6. The system of claim 1, wherein the one or more operations comprises modifying one or more functions of the one or more appliances based on the presence of the floating neutral condition.

7. The system of claim 1, wherein the one or more operations comprises recording an internal fault associated with the one or more appliances based on the presence of the floating neutral condition.

8. A method for detecting a presence of a floating neutral condition, comprising:
instructing, using a control circuit, one or more appliances to:
record a first set of voltage data corresponding to at least one terminal of an electrical circuit, wherein the one or more appliances are electrically connected to corresponding terminals of the electrical circuit;
apply a load on the electrical circuit;
record a second set of voltage data corresponding to the at least one terminal after the load is applied; and
transmit the first set of voltage data and the second set of voltage data to the control circuit; and
analyzing, using the control circuit, the first set of voltage data and the second set of voltage data to detect a presence of a floating neutral condition; and
instructing, using the control circuit, the one or more appliances to execute one or more operations based on the presence of the floating neutral condition.

9. The method of claim 8, wherein method further comprises:
labeling, using the control circuit, the one or more appliances to its corresponding electrical leg of the electrical circuit based on the first set of voltage data and the second set of voltage data; and
detecting, using the control circuit, the presence of the floating neutral condition based on the labeling, the first set of voltage data, and the second set of voltage data.

10. The method of claim 8, wherein the one or more operations comprises generating a notification based on the presence of the floating neutral condition.

11. The method of claim 10, wherein generating the notification comprises transmitting the notification on a user interface associated with a user device.

12. The method of claim 10, wherein generating the notification comprises displaying the notification using a graphical user interface associated with the one or more appliances.

13. The method of claim 8, wherein the one or more operations comprise modifying one or more functions of the one or more appliances based on the presence of the floating neutral condition.

14. The method of claim 8, wherein the one or more operations comprise recording an internal fault associated with the one or more appliances based on the presence of the floating neutral condition.

15. An appliance configured to detect a presence of a floating neutral condition, the appliance comprising:
a control circuit configured to instruct one or more appliances to:
record a first set of voltage data corresponding to at least one terminal of an electrical circuit;
apply a load on the electrical circuit;
record a second set of voltage data corresponding to the at least one terminal after the load is applied; and
transmit the first set of voltage data and the second set of voltage data to the control circuit; and
the control circuit is further configured to:
analyze the first set of voltage data and the second set of voltage data to detect a presence of a floating neutral condition; and
instruct the one or more appliances to execute one or more operations based on the presence of the floating neutral condition.

16. The appliance of claim 15, wherein the control circuit is further configured to:
label, using the control circuit, the one or more appliances according to its corresponding electrical leg of the electrical circuit based on the first set of voltage data and the second set of voltage data; and
detect, using the control circuit, the presence of a floating neutral condition based on the labeling, the first set of voltage data, and the second set of voltage data.

17. The appliance of claim 15, wherein the one or more operations comprise:
generating a notification based on the presence of the floating neutral condition; and
transmitting the notification to a user interface associated with a user device.

18. The appliance of claim 15, wherein the one or more operations comprise:
generating a notification based on the presence of the floating neutral condition; and
displaying the notification using a graphical user interface associated with the one or more appliances.

19. The appliance of claim 15, wherein the one or more operations comprise modifying one or more functions of the one or more appliances based on the presence of the floating neutral condition.

20. The appliance of claim 15, wherein the one or more operations comprise recording an internal fault associated with the one or more appliances based on the presence of the floating neutral condition.
